(19) United States
(12) Patent Application Publication
(10) Pub. No.: US 2025/0248274 A1
(43) Pub. Date: Jul. 31, 2025

(54) ADHESION PROMOTION LAYER TO PREVENT OH ROOF/BODY DELAMINATION FROM ANODE SURFACE

(71) Applicant: Applied Materials, Inc., Santa Clara, CA (US)

(72) Inventor: Jungmin LEE, Santa Clara, CA (US)

(21) Appl. No.: 18/959,303

(22) Filed: Nov. 25, 2024

Related U.S. Application Data
(60) Provisional application No. 63/626,999, filed on Jan. 30, 2024.

(51) Int. Cl. H10K 59/80; H10K 59/12; H10K 71/60

(52) U.S. Cl. CPC H10K 59/873; H10K 59/1201; H10K 59/8051; H10K 71/60

(57) ABSTRACT

Embodiments described herein generally relate to a display. More specifically, embodiments described herein relate to sub-pixel circuits and methods of forming sub-pixel circuits that may be utilized in a display such as an organic light-emitting diode (OLED) display. In an embodiment, a sub-pixel circuit is provided. The sub-pixel circuit includes a substrate, a plurality of sub-pixels, and a cathode ring disposed around a perimeter of the sub-pixel circuit. Each sub-pixel of the plurality of sub-pixels includes a plurality of overhang structures disposed over the substrate, the overhang structures including a first structure, a second structure and an extension disposed past a sidewall of the first structure, a metal structure disposed over the substrate, an adhesion layer disposed under first structure of the plurality of overhang structures, an overhang gap fill structure, an organic OLED material disposed over the metal structure, and a cathode disposed over the OLED material.

### CROSS-REFERENCE TO RELATED APPLICATION

This application claims the benefit of U.S. Provisional Patent Application No. 63/626,999, filed Jan. 30, 2024, which is incorporated by reference herein in its entirety.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are improved sub-pixel circuits and methods of forming sub-pixel circuits.

### SUMMARY

Embodiments described herein generally relate to a display. More specifically, embodiments described herein relate to sub-pixel circuits and methods of forming sub-pixel circuits that may be utilized in a display such as an organic light-emitting diode (OLED) display.

In one embodiment, a sub-pixel circuit is provided. The sub-pixel includes a substrate, a plurality of metal structures disposed over the substrate, an overhang gap fill structures, an overhang structures, the overhang structures including an extension disposed past a sidewall of the overhang structures, an adhesion layer disposed over each overhang gap fill structures, an organic light-emitting diode (OLED) material disposed over the metal structure, and a cathode disposed over the OLED material and a cathode ring disposed over the substrate.

In another embodiment, a sub-pixel circuit is provided. The sub-pixel circuit includes a substrate, a plurality of sub-pixels and a cathode ring disposed around a perimeter of the sub-pixel circuit. Each sub-pixel of the plurality of sub-pixels includes a plurality of overhang structures disposed over the substrate, the overhang structures including a first structure, a second structure and an extension disposed past a sidewall of the first structure, a metal structure disposed over the substrate, an adhesion layer disposed under first structure of the plurality of overhang structures, an overhang gap fill structure, an organic light-emitting diode (OLED) material disposed over the metal structure, and a cathode disposed over the OLED material.

In another embodiment, a method is provided. The method includes depositing an adhesion material over a substrate, the substrate including a plurality of metal structures, a plurality of overhang gap fill structures and a cathode ring, removing portions of the adhesion material, such that an adhesion layer is disposed at least partially over the plurality of overhang gap fill structures, forming overhang structures over the adhesion layer disposed over a plurality of overhang gap fill structures, the overhang structures including an extension disposed past a sidewall of the overhang structures, depositing an organic light-emitting diode (OLED) material over the substrate, the OLED material is disposed over the metal structures, and depositing a cathode, wherein the cathode is disposed under each extension of the overhang structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit along a pixel-line at section line 1A-1A, according to embodiments.

FIG. 1B is a schematic cross-sectional view of a sub-pixel circuit along the line plane at section line 1B-1B, according to embodiments.

FIG. 2 is a schematic, top view of a sub-pixel circuit, according to embodiments.

FIG. 3 is a flow diagram of a method for forming a sub-pixel circuit, according to one or more embodiments.

FIGS. 4A-4E are schematic, cross-sectional views of a substrate during a method of FIG. 3 for forming a sub-pixel circuit, according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. The sub-pixel circuits include an adhesion layer. The adhesion layer promotes adhesion between the overhang structures and at least the overhang gap fill structures.

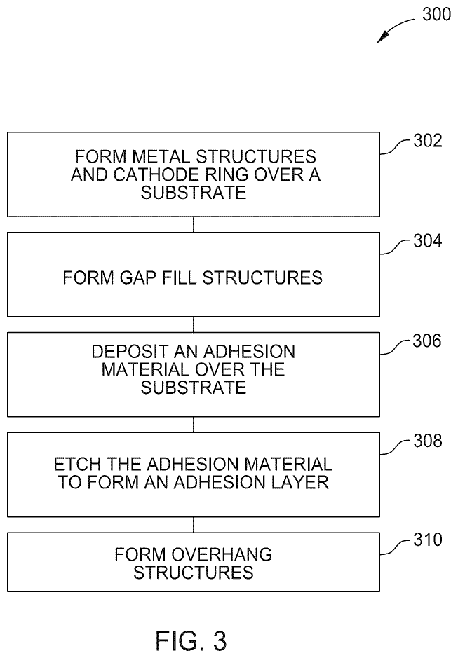

Each sub-pixel circuit includes at least one a sub-pixel. The sub-pixel includes a substrate, a metal structure (e.g., an anode), overhang structures, overhang gap fill structures, separation gap fill structures, an organic light emitting diode (OLED) material, an adhesion layer, and a cathode. The metal structure is defined by adjacent first overhang structure and adjacent second overhang structure. The overhang structures are disposed over the overhang gap fill structures. The overhang structures include a second structure disposed over the first structure. A bottom surface of the second structure extends laterally past an upper surface of the first structure to form an extension. The OLED material is disposed over the anode. The cathode is disposed over the OLED material. The adhesion layer is deposited over the overhang gap fill. The overhang gap fill structures are between adjacent anodes. The sub-pixel circuit includes a cathode ring. The cathode ring surrounds the perimeter of the sub-pixel circuit, as shown in FIG. 2. In one or more embodiments the second structure of the overhang structures extends at least partially over the cathode ring.

Each of the embodiments described herein of the sub-pixel circuit include a plurality of sub-pixels. Each of the sub-pixels is defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel includes OLED materials configured to emit a white, red, green, blue or other color light when energized. For example, the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, e.g., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

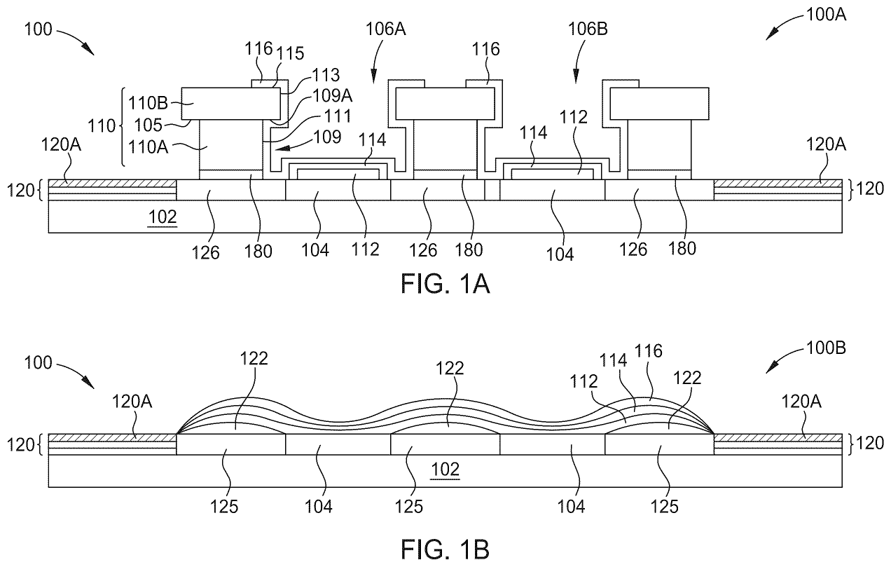

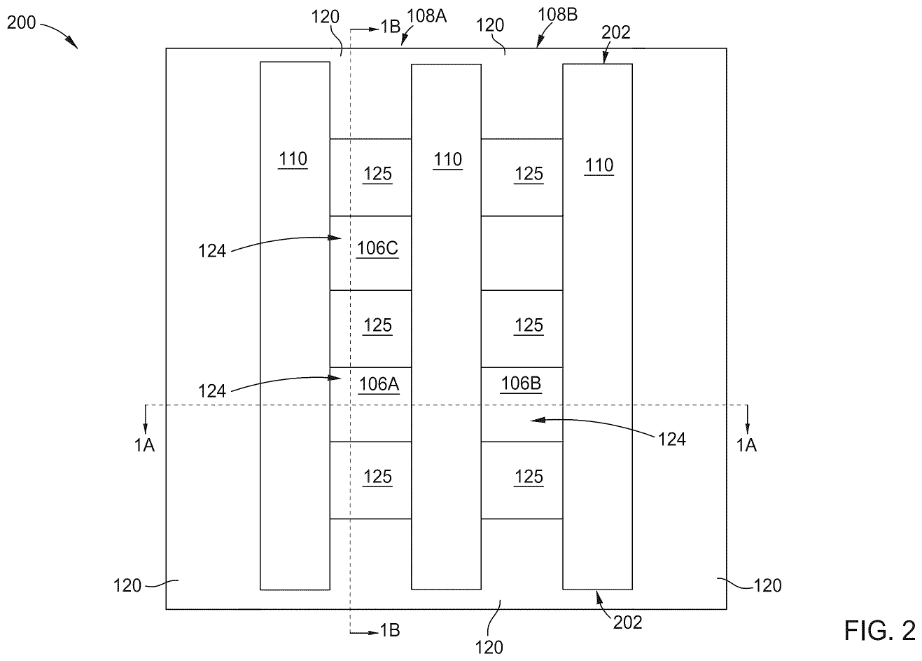

FIG. 1A is a schematic, cross-sectional view of a sub-pixel circuit 100 along the pixel plane 100A. The cross-sectional view of FIG. 1A is taken along section line 1A-1A of FIG. 2. The pixel plane 100A corresponds to an X-direction. FIG. 1C is a schematic, cross-sectional view of a sub-pixel circuit 100 along the line plane 100B. The cross-sectional view of 1B is taken along section line 1B-1B of FIG. 2. The line plane 100B corresponds to the Y-direction. FIG. 1A shows a first sub-pixel 106A and a second sub-pixel 106B. The sub-pixel circuit 100 includes a substrate 102, metal structures 104, gap fill structures (e.g., overhang gap fill structures 126 or separation gap fill structures 125), a cathode ring 120, overhang structures 110, an adhesion layer 180, OLED material 112, a cathode 114, and an encapsulation layer 116.

The sub-pixel circuit 100 includes a substrate 102. The sub-pixel circuit 100 includes a substrate 102. In one or more embodiments, the substrate 102 is a backplane. The backplane includes, but is not limited to, a complementary metal-oxide-semiconductor (CMOS) array, a thin-film transistor (TFT) array, or a glass backplane. In one or more embodiments, the metal structures 104 are pre-patterned on the substrate 102. For example, the substrate is pre-patterned with metal structures 104 (e.g., anodes) including a metal-containing material. The metal-containing material includes indium tin oxide (ITO), chromium, chromic oxide (Cr₂O₃), titanium, gold, silver, copper, aluminum, a transparent conductive oxide (TCO), combinations thereof, or other suitably conductive materials. The metal structures 104 are configured to operate as anodes of respective sub-pixels. In one embodiment, the metal structures 104 is a layer stack of a first transparent conductive oxide (TCO) layer, a second metal-containing layer disposed on the first TCO layer, and a third TCO layer disposed on the second metal-containing layer.

The cathode ring 120 surrounds the perimeter of the sub-pixel circuit 100. As shown in FIG. 1A and 1B, the cathode ring 120 includes at least one layer. The at least one layer includes a metal containing material. The metal containing material includes, but is not limited to a transparent conductive oxide (TCO) material, tin (IV) oxide (SnO₂), aluminum (Al), titanium nitride (TiN), or combinations thereof. The TCO may be indium tin oxide (ITO). The cathode ring 120, in some embodiments, includes a layer stack. The layer stack includes at least three layers. For example, the layer stack includes a first transparent conductive oxide TCO layer, a second metal-containing layer disposed on the first TCO layer, and a third TCO layer disposed on the second metal-containing layer. For example, the cathode ring 120 includes an Al layer, a TiN layer, and a SnO₂ layer. In this example, the Al layer includes a thickness of about 200 nm to about 300 nm, the TiN layer includes a thickness of less than 10 nm, and the SnO₂ layer is less than 20 nm. The metal-containing material of the cathode ring 120 with a single layer or at least one of the layers of the layer stack may include the same material as the metal structures 104 (e.g., the cathode ring 120 and the metal structures 104 include the same metal-containing material and/or same layer stack). The cathode ring 120 contacts at least one gap fill structure. For example, as shown in FIG. 1A, the cathode ring 120 contacts at least one of the overhang gap fill structures 126. For example, as shown in FIG. 1B, the cathode ring 120 contacts at least one of the separation gap fill structures 125.

As shown in FIG. 1A, one or more overhang gap fill structures 126 are disposed over the substrate 102. The overhang gap fill structures 126 includes one of an organic material, an organic material with an inorganic coating disposed thereover, or an inorganic material. The organic material of the overhang gap fill structures 126 includes, but is not limited to, polyimides. The inorganic material of the overhang gap fill structures 126 includes, but is not limited to, silicon oxide (SiO₂), silicon nitride (Si₃N₄), silicon oxynitride (Si₂N₂O), magnesium fluoride (MgF₂), or combinations thereof. An adhesion layer 180 is disposed over each overhang gap fill structures 126 to promote adhesion between the first structure 110A of each overhang structure 110 and the overhang gap fill structures 126. In one or more embodiments, the adhesion layer 180 promotes adhesion between the first structure 110A of the overhang structure 110 and the metal structure 104 or the substrate 102. The adhesion layer 180 is any TCO, an oxide-containing layer or a silicon-containing layer. The silicon-containing layer may include silicon nitride (SiNx) layer. The oxide-containing layer may include tin oxide (SnO₂). The TCO layer may include indium gallium zinc oxide (IGZO), indium zinc oxide (IZO), ITO, or any similar material.

As shown in FIG. 1B, the sub-pixel circuit 100 includes separation gap fill structures 125. Each sub-pixel line (e.g., a first sub-pixel line 108A or a second sub-pixel line 108B as shown in FIG. 2) includes separation gap fill structures 125, with adjacent sub-pixels sharing the separation gap fill structures 125. The separation gap fill structures 125 are permanent to the sub-pixel circuit 100. The separation gap fill structures 125 further define each sub-pixel (e.g., a first sub-pixel 106A and a third sub-pixel 106C) of a first sub-pixel line 108A of the sub-pixel circuit 100. The separation gap fill structures 125 may also be known as gap-fill between adjacent anodes. In one or more embodiments, an aluminum oxide layer 122 is disposed over the separation gap fill structures 125.

The sub-pixel circuit 100 has a plurality of sub-pixel lines (e.g., a first sub-pixel line 108A or a second sub-pixel line 108B in FIG. 2). The sub-pixel lines (e.g., the first sub-pixel line 108A and a second sub-pixel line 108B) are adjacent to each other along the pixel plane 100A. While FIG. 1A depicts the first sub-pixel line 108A and the second sub-pixel line 108B, the sub-pixel circuit 100 of the embodiments described herein may include two or more sub-pixel lines, such as a third sub-pixel line and a fourth sub-pixel line. Each sub-pixel line includes OLED material 112 configured to emit a white, red, green, blue or other color light when energized. In some embodiments, the OLED material 112 within a pixel line (e.g., the first sub-pixel line 108A and the second sub-pixel line) are configured to emit the same color light when energized. In other embodiments, the OLED material 112 within a pixel line (e.g., a first sub-pixel line 108A and the second sub-pixel line 108B) are configured to emit different colors of light when energized. For example, the OLED material 112 of the first sub-pixel line 108A emits a red light when energized, the OLED materials of the second sub-pixel line 108B emits a green light when energized, the OLED materials of the third sub-pixel line emits a blue light when energized (not pictured), and the OLED materials of a fourth sub-pixel (not pictured) emits another color light when energized. For example, the OLED materials of the first sub-pixel 106A emit a red light when energized and the OLED materials of the second sub-pixel 106B emit a green light when energized.

Each sub-pixel line includes overhang structures 110, with adjacent sub-pixel lines sharing the overhang structures 110 in the pixel plane. The overhang structures 110 are permanent to the sub-pixel circuit 100. The overhang structures 110 further define each sub-pixel line of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. In one or more embodiments, the first structure 110A contacts the adhesion layer 180. The adhesion layer 180 promotes adhesion between the first structure 110A and the overhang gap fill structures 126. In one or more embodiments, at least one of the overhang extensions 109A extends at least partially over the cathode ring 120.

The first structure 110A includes a non-conductive material or a conductive material. The second structure 110B includes a non-conductive material or a conductive material. In some embodiments, the first structure 110A and the second structure 110B include the same material. In other embodiments, the first structure 110A and the second structure 110B include a different material. The non-conductive material includes a titanium containing material or a silicon-containing material. The silicon-containing material includes, but is not limited to, amorphous silicon (a-Si), silicon nitride (Si₃N₄), silicon oxide (SiO₂), silicon oxynitride (Si₂N₂O), or combinations thereof. The conductive material includes, but is not limited to, aluminum (Al), aluminum neodymium (AlNd), molybdenum (Mo), molybdenum tungsten (MoW), copper (Cu), or combinations thereof.

The overhang extension 109A of the second structure 110B forms the adjacent overhangs 109 and allows for the second structure 110B to shadow the first structure 110A. The shadowing of the adjacent overhangs 109 provides for evaporation deposition of an OLED material 112 and a cathode 114. The OLED material 112 may include one or more of a hole injection layer (HIL), a hole transport layer (HTL), an emissive layer (EML), and an electron injection layer (EIL), and an electron transport layer (ETL). The OLED material 112 is disposed over and in contact with the metal structures 104. The OLED material 112 is disposed under adjacent overhangs 109 and may contact a sidewall 111 of the first structure 110A. In one embodiment, the OLED material 112 is different from the material of the first structure 110A, the second structure 110B, and the overhang gap fill structures 126. The cathode 114 is disposed over the OLED material 112 and extends under the adjacent overhangs 109. The cathode 114 extends past an endpoint of the OLED material 112.

The cathode 114 includes a conductive material, such as a metal. For example, the cathode 114 includes, but is not limited to, silver, magnesium, chromium, titanium, aluminum, ITO, or a combination thereof. In one embodiment, material of the cathode 114 is different from the material of the first structure 110A and the second structure 110B. In one or more embodiments the OLED material 112 and the cathode 114 do not contact the sidewall 111 of the first structure 110A. In one or more embodiments, the OLED material 112 contacts the sidewall 111 of the first structure 110A.

Each sub-pixel (e.g., a first sub-pixel 106A and a second sub-pixel 106B) includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the overhang extension 109A and along a sidewall 111 of each of the first structure 110A and the second structure 110B. The encapsulation layer 116 is disposed over the cathode 114 and extends past the cathode 114, between the cathode and the sidewall 111, and at least partially over the sidewall 111. In some embodiments, the encapsulation layer 116 extends to contact the sidewall 111 of the first structure 110A. In the illustrated embodiment in FIG. 1A, the encapsulation layer 116 extends to contact the second structure 110B at an underside surface of the overhang extension 109A, the sidewall 113 of the second structure 110B, and the upper surface 115 of the second structure 110B. In some embodiments, the encapsulation layer 116 extends to contact the second structure 110B at an underside surface of the overhang extension 109A and to be disposed over the adhesion layer 180, the OLED material 112, and the cathode 114. In other embodiments, the encapsulation layer 116 ends at the sidewall 111 of the first structure 110A (e.g., is not disposed over the sidewall 113 of the second structure 110B, the upper surface 115 of the second structure 110B, or the underside surface of the overhang extension 109A of the overhang structures 110). The encapsulation layer 116 includes the non-conductive inorganic material, such as the silicon-containing material. The silicon-containing material may include Si₃N₄ containing materials.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels (e.g., a first sub-pixel 106A and a second sub-pixel 106B), and disposed between the encapsulation layer 116 and the global passivation layer.

FIG. 2 is a schematic, top view of sub-pixel circuit 100, having an architecture 200 according to embodiments. The architecture 200 includes a plurality of pixel openings 124. Each of pixel opening 124 is abutted by overhang structures 110 and a separation gap fill structures 125 which define each of the sub-pixel line (e.g., a first sub-pixel line 108A and a second sub-pixel line 108B) and sub-pixel pixel (e.g., a first sub-pixel 106A and a second sub-pixel 106B) of the architecture 200. Evaporation deposition is utilized for deposition of OLED materials (including a hole injection layer (HIL), a hole transport layer (HTL), an emissive layer (EML), and an electron transport layer (ETL)). Evaporation deposition is used for deposition of inorganic materials and cathode material. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, e.g., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

The cathode ring 120 surrounds the perimeter of the sub-pixel circuit 100 of the architecture 200. As shown in FIG. 2 the cathode ring 120 is shown as a rectangle. However, it is contemplated the cathode ring 120 may be any shape such that it surrounds the perimeter of the sub-pixel circuit 100. In one or more embodiments, the overhang extension 109A of the second structure 110B extends at least partially over the cathode ring 120 as shown by portion 202 of the second structure 110B.

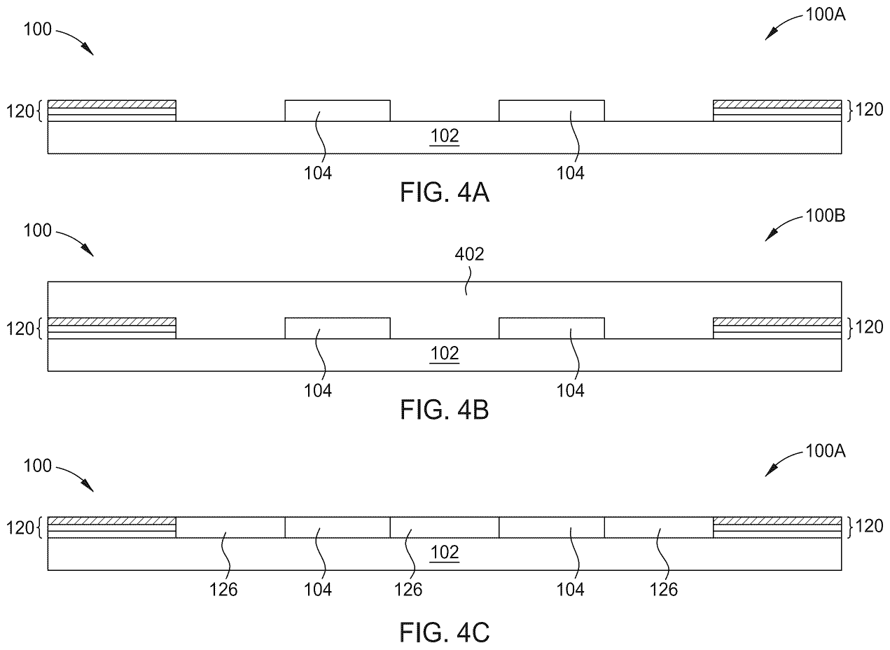

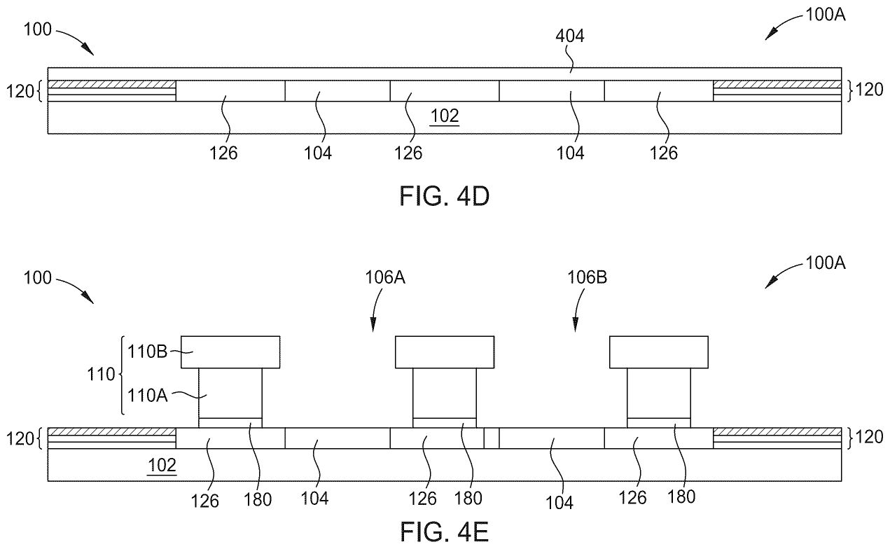

FIG. 3 is a flow diagram of method 300 for forming a sub-pixel circuit 100. The method 300 forms a sub-pixel circuit 100 with an adhesion layer 180 disposed over an overhang gap fill structures 126. FIG. 4A-4E are schematic, cross-sectional views of substrate 102 during the method 300 for forming the sub-pixel circuit 100.

At operation 302, as shown in FIG. 4A, metal structures 104 (e.g., anodes) and a cathode ring 120 are formed over a substrate. This can be done by depositing a metal material layer over the substrate 102, and then depositing a photoresist pattern over the metal material layer. The metal material layer (not protected by a photoresist pattern) is then etched away forming the desired pattern of the metal structures 104 (e.g., anode structures). The cathode ring 120 is formed via depositing a cathode material layer over the substrate 102, and then depositing a photoresist pattern over the cathode material layer. The metal material layer (not protected by a photoresist pattern) is then etched away, forming the desired pattern of the cathode ring 120. For example, the cathode ring 120 is a rectangle around the sub-pixel circuit 100, as shown in FIG. 2. In one or more embodiments, the metal structures 104 and the cathode ring 120 are formed from the same material so that the metal structures 104 and the cathode ring 120 are formed simultaneously. For example, a metal material is deposited over the substrate 102. A photoresist is deposited in a pattern over the metal material, and the material not protected by the photoresist is etched away. The material protected by the photoresist forms the metal structures 104 and the cathode ring 120. In one or more embodiments, the metal structures 104 and the cathode ring 120 include a plurality of layers. The layers may include different material or the same material. In the embodiments including a plurality of layers, the process of depositing the material, depositing a photoresist, and etching may be repeated. Additionally or alternatively, the process of depositing the metal structures 104 and the cathode ring 120 is repeated and the process of depositing a photoresist and etching occurs to form the pattern of the metal structures 104 and cathode ring 120. In one or more embodiments, the metal structures 104 and the cathode ring 120 include the same height, which may be completed during the etching process or an additional planarization process. Additionally or alternatively, the metal structures 104 and the cathode ring 120 include different heights.

At operation 304, as shown in FIGS. 4B and 4C (along the pixel plane 100A, section line 1A-1A shown in FIG. 2), gap fill structures are formed. A gap fill material 402 is deposited over the metal structures 104, the cathode ring 120, and the substrate 102. The gap fill material 402 is then etched away to form the overhang gap fill structures 126 in between the metal structures 104 and the cathode ring 120 as shown in FIG. 4C. The overhang gap fill structures 126 are then planarized such that that a top surface of each overhang gap fill structures 126 are aligned with one another and the upper surface of the metal structures 104, as shown in FIG. 4C (e.g., the overhang gap fill structures 126 and the metal structures 104 include the same height). Additionally or alternatively, the cathode ring 120 is planarized such that the top surface of each overhang gap fill structures 126, each metal structure 104, and the top surface 120A of the cathode ring 120 include the same height.

At operation 306, as shown in FIG. 3D an adhesion material 404 is deposited over the substrate. The adhesion material 404 is deposited over the metal structures 104, the cathode ring 120, and the overhang gap fill structures 126. In one or more embodiments, the adhesion material 404 is deposited using evaporation deposition. At operation 308, the adhesion material is etched to form an adhesion layer. A photoresist is disposed over portions of the adhesion material 404. The photoresist is patterned to protect portions of the adhesion material 404 from the etching process. The photoresist is patterned so that it protects the portions of the adhesion material 404 disposed over the overhang gap fill structures 126. The adhesion material 404 is etched away over the metal structures 104 and the cathode ring 120.

At operation 310, as shown in FIG. 3E, overhang structures 110 are formed. The overhang structures 110 are formed over the adhesion layer 180 and each overhang gap fill structures 126. The overhang structures 110, as shown in FIG. 3E, can be formed by depositing a first overhang layer and a second overhang layer, and etching away the desired areas using a photoresist in order to form the overhang structures.

After operation 310, further processing may occur. For example, deposition of OLED materials, a cathode, and an encapsulation layer may occur to complete the sub-pixel circuit 100. Operations may repeat until the number of desired sub-pixels are formed. An example of a complete sub-pixel is shown in FIG. 1A.

In summation, a device is disclosed. The device is a sub-pixel circuit, which includes a substrate, a plurality of sub-pixels, and a cathode ring. The sub-pixels are formed over the substrate. The sub-pixels each include at least a metal structure (e.g., an anode), an adhesion layer, overhang structures, gap fill structures, an organic light emitting diode (OLED) material, a cathode, and encapsulation material. The metal structure is defined by adjacent overhang structures. The overhang structures are disposed over the adhesion layer. The overhang structures include a second structure disposed over the first structure. A bottom surface of the second structure extends laterally past an upper surface of the first structure. The OLED material is disposed over the metal structure and the inorganic layer. The cathode is disposed over the OLED material. The encapsulation layer is disposed over at least the cathode material. The cathode ring is disposed around the perimeter of the sub-pixel circuit. In one or more embodiments, the second portion of the overhang structure extends over at least a portion of the cathode ring. The adhesion layer provided herein reduces delamination and increases adhesion between the gap fill material and the overhang structures.

While the foregoing is directed to embodiments of the present disclosure, other and further embodiments of the disclosure may be devised without departing from the basic scope thereof, and the scope thereof is determined by the claims that follow.

1. A sub-pixel circuit comprising:
a substrate;
a plurality of metal structures disposed over the substrate;
a plurality of overhang gap fill structures;
a plurality of overhang structures, the plurality of overhang structures including an extension disposed past a sidewall of the overhang structure;
an adhesion layer disposed over each overhang gap fill structure;
an organic light-emitting diode (OLED) material disposed over each metal structure;
a cathode disposed over the OLED material; and
a cathode ring disposed over the substrate.

2. The sub-pixel circuit of claim 1, wherein adjacent overhang gap fill structures have at least one of the plurality of metal structures disposed therebetween.

3. The sub-pixel circuit of claim 1, wherein the cathode ring is disposed around a perimeter of the sub-pixel circuit.

4. The sub-pixel circuit of claim 3, wherein the sub-pixel circuit includes at least two sub-pixels.

5. The sub-pixel circuit of claim 1, wherein the adhesion layer comprises tin oxide (SnO₂).

6. The sub-pixel circuit of claim 1, further comprising an encapsulation layer disposed over the cathode and past an endpoint of the cathode.

7. The sub-pixel circuit of claim 1, wherein the cathode ring comprises a plurality of layers.

8. The sub-pixel circuit of claim 1, wherein the cathode ring and the metal structures comprise a same material.

9. A sub-pixel circuit, the sub-pixel circuit comprising:
a substrate;
a plurality of sub-pixels, each sub-pixel of the plurality of sub-pixels comprising:
a plurality of overhang structures disposed over the substrate, the overhang structures comprising:
a first structure;
a second structure; and
an extension disposed past a sidewall of the first structure;
a metal structure disposed over the substrate;
an adhesion layer disposed under first structure of the plurality of overhang structures;
an overhang gap fill structure;
an organic light-emitting diode (OLED) material disposed over the metal structure; and
a cathode disposed over the OLED material; and
a cathode ring disposed around a perimeter of the sub-pixel circuit.

10. The sub-pixel circuit of claim 9, wherein the adhesion layer is deposited using evaporation deposition.

11. The sub-pixel circuit of claim 9, wherein the overhang gap fill structure is disposed under the first structure of each overhang structure of the plurality of overhang structures.

12. The sub-pixel circuit of claim 9, wherein adjacent overhang gap fill structures have the metal structure disposed therebetween.

13. The sub-pixel circuit of claim 9, wherein the cathode ring and the metal structure comprise a same material.

14. The sub-pixel circuit of claim 9, further comprising:
an encapsulation layer disposed over the cathode and past an endpoint of the cathode, wherein the encapsulation layer extends under at least a portion of the extension of overhang structures, along the sidewall of the overhang structures, and contacts a bottom surface of the extension of the overhang structures.

15. A method, comprising:
depositing an adhesion material over a substrate, the substrate including a plurality of metal structures, a plurality of overhang gap fill structures and a cathode ring;
removing portions of the adhesion material, such that an adhesion layer is disposed at least partially over the plurality of overhang gap fill structures;
forming overhang structures over the adhesion layer disposed over the plurality of overhang gap fill structures, the overhang structures including an extension disposed past a sidewall of the overhang structures;
depositing an organic light-emitting diode (OLED) material over the substrate, the OLED material is disposed over the metal structures; and
depositing a cathode, wherein the cathode is disposed under each extension of the overhang structures.

16. The method of claim 15, further comprising:
depositing an encapsulation layer over the cathode and past an endpoint of the cathode, wherein the encapsulation layer extends under at least a portion of the extension of overhang structures, along the sidewall of the overhang structures, and contacts a bottom surface of the extension of the overhang structures.

17. The method of claim 15, wherein the plurality of metal structures comprises a plurality of layers and the cathode ring comprises a plurality of layers.

18. The method of claim 15, wherein the plurality of metal structures and the cathode ring are deposited simultaneously onto the substrate.

19. The method of claim 15, wherein portions of the adhesion layer are removed by an etching process.

20. The method of claim 15, wherein the adhesion layer comprises tin oxide (SnO₂).
